(19) United States
(12) Patent Application Publication
(10) Pub. No.: US 2010/0213450 A1
(43) Pub. Date: Aug. 26, 2010

(54) PHOSPHOR ELEMENT AND DISPLAY DEVICE

(76) Inventors: Eiichi Satoh, Osaka (JP); Takayuki Shimamura, Osaka (JP); Reiko Taniguchi, Osaka (JP); Shogo Nasu, Hyogo (JP); Masayuki Ono, Osaka (JP); Masaru Odagiri, Hyogo (JP)

Correspondence Address: MCDERMOTT WILL & EMERY LLP, 600 13TH STREET, NW, WASHINGTON, DC, 20005-3096, US

(21) Appl. No.: 12/682,745

(22) PCT Filed: Oct. 9, 2008
(86) PCT No.: PCT/JP2008/002848

§ 371 Date: Apr. 12, 2010

(30) Foreign Application Priority Data
Oct. 12, 2007 (JP) 2007-266828

(51) Int. Cl. H01L 51/54

(52) U.S. Cl. 257/40; 257/E51.027

(57) ABSTRACT

A phosphor element is provided with a first electrode and a second electrode. The electrodes are arranged to face each other, and at least one of the electrodes is transparent or semi-transparent. The phosphor element is also provided with a phosphor layer, which is sandwiched between the first electrode and the second electrode and has phosphor particles dispersed in a medium made of a hole transport material. Conductive nano particles are held on the surface of each of the phosphor particles.

### BACKGROUND

1. Technical Field

The present invention relates to a phosphor element for electroluminescence. Furthermore, the present invention relates to a light emitting device using the phosphor element.

2. Description of the Related Art

In recent years, electroluminescence elements (hereinafter, referred to as EL elements) have attracted attention as light and thin surface-emitting elements. The EL elements are broadly divided into organic EL elements in which a direct-current voltage is applied to a fluorescent substance made of an organic material to recombine electrons and holes for light emission, and inorganic EL elements in which an alternating voltage is applied to a fluorescent substance made of an inorganic material to induce electrons accelerated in a high electric field of approximately 10⁶ V/cm to collide with the luminescent center of the inorganic fluorescent substance for excitation of the electrons, and permit the inorganic fluorescent substance to emit light in the relaxation process.

The inorganic EL elements include dispersion EL elements in which inorganic fluorescent substance particles are dispersed in a binder made of a polymer organic material to serve as a phosphor layer, and thin-film EL elements in which an insulating layer is provided on one or both sides of a thin-film phosphor layer with a thickness on the order of 1 μm. Among these elements, the dispersion EL elements have attracted attention because of the advantages of their lower power consumption and even lower manufacturing cost due to their simpler manufacturing processes.

The EL element referred to as a dispersion EL element will be described. Conventional EL elements have a layered structure including a substrate, a first electrode, a phosphor layer, an insulating layer, and a second electrode in order from the substrate side. The phosphor layer includes inorganic fluorescent substance particles such as ZnS:Mn dispersed in an organic binder, and the insulating layer includes a strong insulator such as BaTiO₃ dispersed in an organic binder. An alternating-current power supply is placed between the first electrode and the second electrode, and a voltage is applied from the alternating-current power supply to the first electrode and the second electrode to permit the EL element to emit light.

In the structure of the dispersion EL element, the phosphor layer is a layer which determines the luminance and efficiency of the dispersion EL element, and particles with a size of 15 μm to 35 μm in particle diameter is used for the inorganic fluorescent substance particles of this phosphor layer. Furthermore, the luminescent color of the phosphor layer of the dispersion EL element is determined by the inorganic fluorescent substance particles used in the phosphor layer. For example, orange light emission is exhibited in the case of using ZnS:Mn for the inorganic fluorescent substance particles, and for example, blue-green light emission is exhibited in the case of using ZnS:Cu for the inorganic fluorescent substance particles. As described above, the luminescent color is determined by the inorganic fluorescent substance particles. Thus, when light of other, for example, white luminescent color is to be emitted, an organic dye is mixed into the organic binder to convert the luminescent color, thereby obtaining the intended luminescent color.

However, light emitters for use in the EL elements have the problems of low light emission luminance and short lifetime. As a method for increasing the light emission luminance, a method of increasing the voltage applied to the phosphor layer is conceivable. In this case, there is a problem that the half-life of the light output from the light emitter is decreased in proportion to the applied voltage. On the other hand, as a method for making the half-life longer, that is, making the lifetime longer, a method of decreasing the voltage applied to the phosphor layer is conceivable. However, this method has the problem of decrease in light emission luminance. As described above, the light emission luminance and the half-life have a relationship in which when the voltage applied to the phosphor layer is increased or decreased to try to improve one of the light emission luminance and the half-life, the other will be degraded. Therefore, one will have to select either the light emission or the half-life. It is to be noted that the half-time in the specification refers to a period of time until the light output from the light emitter is decreased to the half output of the original luminance.

Thus, suggestions have been made for driving phosphor elements with low voltages, as described in Japanese Patent Laid-Open Publication No. 2006-120328. According to this suggestion, in a dispersion EL element, a phosphor layer and a dielectric are interposed between a transparent electrode and a rear electrode, and the phosphor layer has an acicular substance with its conductivity higher than that of a fluorescent substance with being dispersed in an organic binder. Since the acicular substance is dispersed, high-energy electrons are permitted to collide efficiently with the fluorescent substance, thereby allowing for a longer lifetime and a higher efficiency.

### SUMMARY

However, it is essential to provide the dielectric layer for constituting dispersion EL, and it is further necessary to apply a high alternating voltage between the electrodes for permitting the phosphor layer to emit light. As a result, the dispersion type EL has a problem that it is hard to obtain long lifetimes and high efficiencies.

An object of the present invention to solve the problem described above and provide a phosphor element which is driven at a low voltage, exhibits a high light emission luminance, and has a long lifetime.

A phosphor element according to the present invention includes: a first electrode and a second electrode arranged to face each other, at least one of the electrodes being transparent or semi-transparent; and a phosphor layer provided as being sandwiched between the first electrode and the second electrode, the phosphor layer having phosphor particles dispersed in a medium made of a hole transport material, wherein conductive nano particles are held on a surface of each of the phosphor particles.

A phosphor element according to the present invention includes: a first electrode and a second electrode arranged to face each other, at least one of the electrodes being transparent or semi-transparent; and a phosphor layer provided as being sandwiched between the first electrode and second electrode, phosphor layer having phosphor particle powder including phosphor particles, conductive nano particles being held on a surface of each of the phosphor particles, hole transport material being held on at least a portion of the surface on which the nano particles.

The conductive nano particles held on the surface of each of the phosphor particles are exposed from the hole transport material to the outside.

The phosphor layer may include a binder among the phosphor particles.

The hole transport material may include an organic hole transport material.

The organic hole transport material may contain components of the following chemical formula 1 and chemical formula 2.

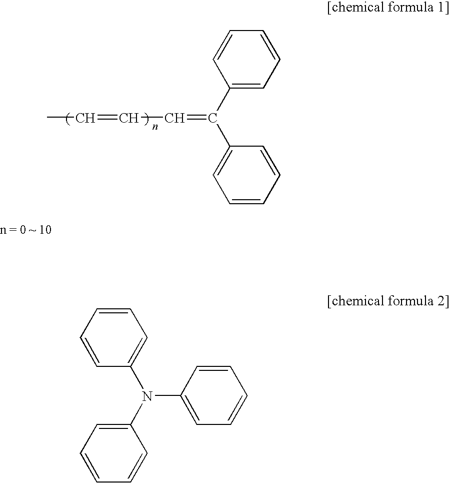

The organic hole transport material may further include at least one component of the group constituting of the following chemical formula 3, chemical formula 4, and chemical formula 5.

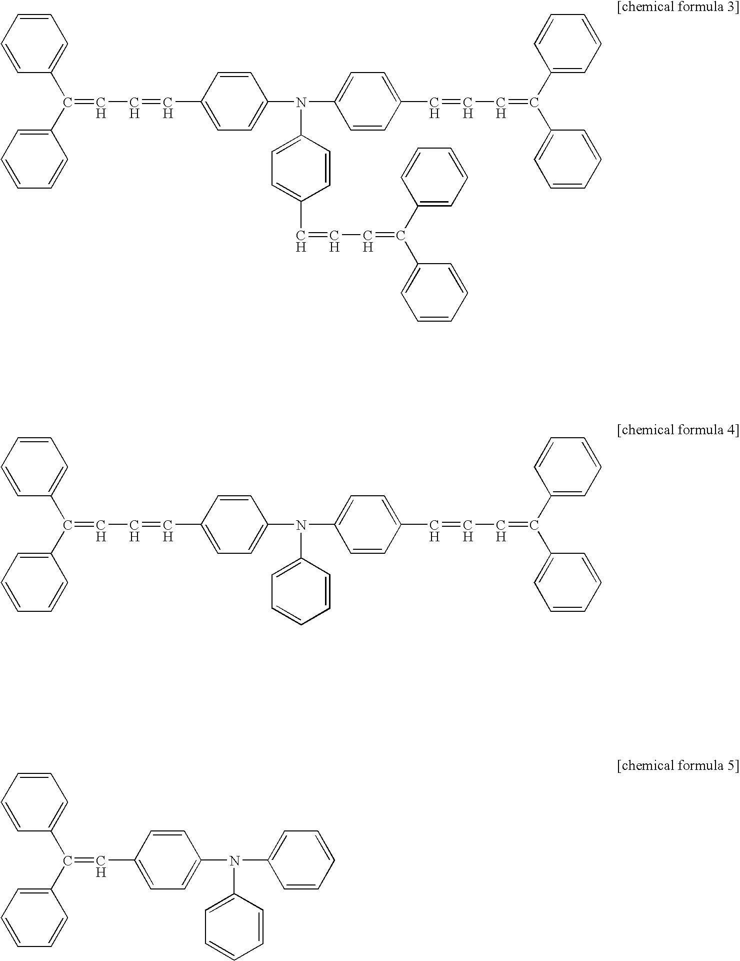

The hole transport material may include an inorganic hole transport material.

The conductive nano particles may include at least one metal fine particle selected from the group constituting of Ag, Au, Pt, Ni, and Cu. The conductive nano particles may include at least one oxide fine particle selected from the group constituting of an indium tin oxide, ZnO, and InZnO. The conductive nano particles may include at least one carbon fine particle selected from the group of fullerene and a carbon nanotube.

The conductive nano particles may have an average particle diameter within the range of 1 nm to 200 nm.

The phosphor particles may include a particle containing a Group XIII-Group XV compound semiconductor. The phosphor particles may include at least one phosphor material selected from the group of a nitride, a sulfide, a selenide, and an oxide. The phosphor particles may be nitride semiconductor particles including at least one element of Ga, Al, and In. The phosphor particles may be phosphor particles containing GaN.

The phosphor particles may have an average particle diameter within the range of 0.1 μm to 1000 μm.

The phosphor element may further include a hole injection layer sandwiched between the first electrode and the phosphor layer.

The phosphor element may further include a support substrate facing the first electrode or the second electrode for support. The support substrate may be a glass substrate or a resin substrate.

The phosphor element may further include one or more thin film transistors connected to the first electrode or the second electrode.

A display device according to the present invention includes: a phosphor element array in which the phosphor element is two-dimensionally arranged in plural; a plurality of x electrodes extending parallel to each other in a first direction parallel to a light emitting surface of the phosphor element array; and a plurality of y electrodes extending parallel to a second direction parallel to the light emitting surface of the phosphor element array and orthogonal to the first direction.

A display device according to the present invention includes: a phosphor element array in which the phosphor element is two-dimensionally arranged in plural; a plurality of signal wirings extending parallel to each other in a first direction parallel to a light emitting surface of the phosphor element array; and a plurality of scan wirings extending parallel to second direction parallel to the light emitting surface of the phosphor element array and orthogonal to the first direction, wherein one electrode connected to the thin film transistor of the phosphor element array is a pixel electrode corresponding to respective intersection of the signal wiring and the scan wiring, whereas the other electrode is provided which is common to the plurality of phosphor elements.

The display device may further include a color conversion layer anteriorly in a direction of light emission extraction.

According to the present invention, it is possible to provide high phosphor elements and display devices which are permitted to emit light with a direct current and a low voltage, exhibit a light emission luminance, and have a long lifetime.

### BRIEF DESCRIPTION OF THE DRAWINGS

The present invention will become readily understood from the following description of preferred embodiments thereof made with reference to the accompanying drawings, in which like parts are designated by like reference numeral and in which:

FIG. 1 is a cross-sectional view perpendicular to a light emitting surface of a phosphor element according to first embodiment of the present invention;

FIG. 2 is a cross-sectional view perpendicular to a light emitting surface of a modification example of the phosphor element according to first embodiment of the present invention;

FIG. 3 is a cross-sectional view perpendicular to a light emitting surface of a modification example of the phosphor element according to first embodiment of the present invention;

FIG. 4 is a cross-sectional view perpendicular to a light emitting surface of a phosphor element according to second embodiment of the present invention;

FIG. 5 is a cross-sectional view illustrating the schematic structure of a light emitting composite particle used in the phosphor element according to second embodiment of the present invention;

FIG. 6 is a cross-sectional view illustrating the schematic structure of a light emitting composite particle used in a phosphor element according to third embodiment of the present invention;

FIG. 7 is a cross-sectional view perpendicular to a light emitting surface of the phosphor element according to third embodiment of the present invention;

FIG. 8 is a schematic perspective view of a phosphor element according to fourth embodiment of the present invention;

FIG. 9 is a schematic perspective view of a display device according to fifth embodiment of the present invention;

FIG. 10 is a schematic perspective view of a display device according to sixth embodiment of the present invention; and

FIG. 11 is a cross-sectional view perpendicular to a light emitting surface of a conventional phosphor element.

### DESCRIPTION OF THE PREFERRED EMBODIMENTS

Phosphor elements according to embodiments of the present invention will be described below with reference to the accompanying drawings. It is to be noted that the practically same members are denoted by the same reference numerals in the drawings.

### First Embodiment

### <Schematic Structure of EL Element>

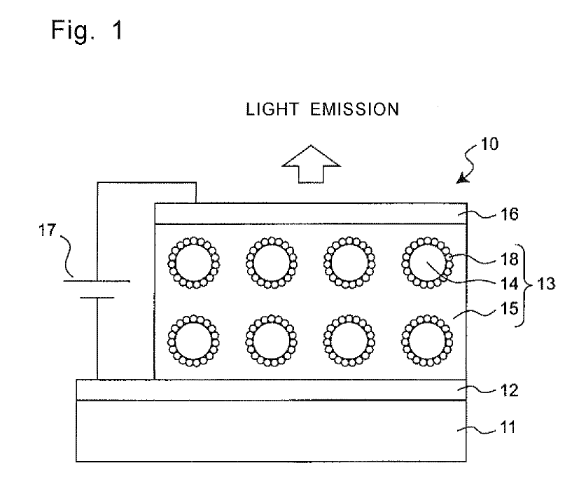

FIG. 1 is a schematic cross-sectional view illustrating the structure of a phosphor element 10 according to first embodiment. This phosphor element 10 includes a rear electrode 12 that is a first electrode, a transparent electrode 16 that is a second electrode, and a phosphor layer 13 sandwiched between the pair of electrodes 12, 16. The phosphor layer 13 has phosphor particle powder dispersed in a hole transport material 15. Conductive nano particles 18 are held on the surface of each of phosphor particles 14. Furthermore, a direct-current power supply 17 is connected between the rear electrode 12 that is the first electrode and the transparent electrode 16 that is the second electrode to apply a voltage therebetween. When power is supplied between the electrodes 12, 16, a potential difference is produced between the rear electrode 12 and the transparent electrode 16, thereby applying a voltage therebetween. Then, holes and electrons as carriers are injected from the rear electrode 12 and the transparent electrode 16 through the conductive nano particles 18 and the hole transport material 15 into the phosphor particles 14, and recombined to emit light. The emitted light is extracted from the transparent electrode 16 side to the outside.

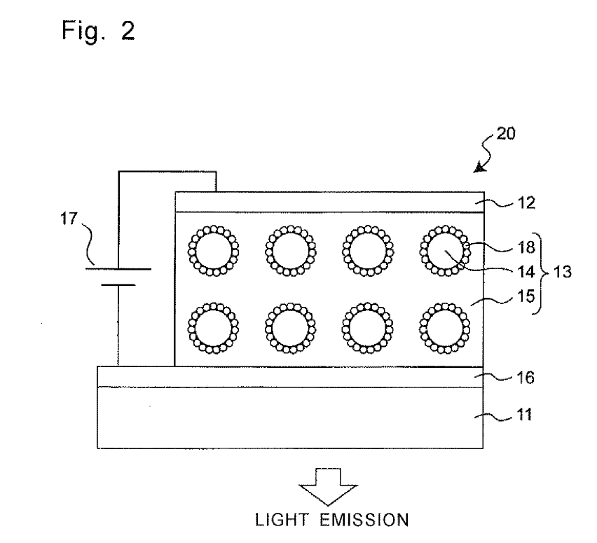

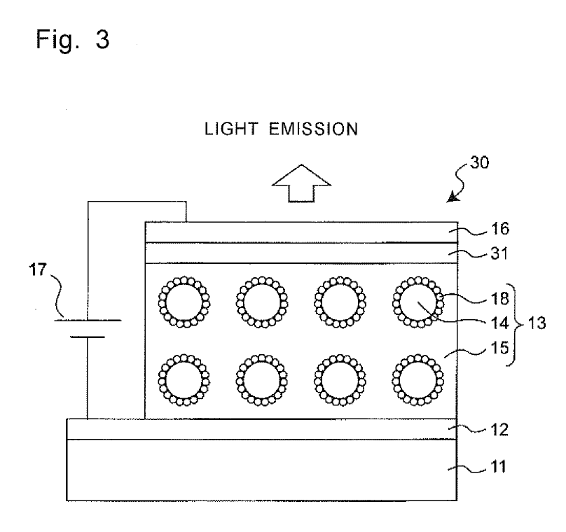

It is to be noted that the present invention is not limited to the structure described above, and changes can be appropriately made, in such a way that the rear electrode 12 and the transparent electrode 16 are interchanged, transparent electrodes are used for both of the electrode 12 and the electrode 16, or an alternating-current power supply is used as the power supply. Furthermore, changes can be appropriately made, in such a way that a black electrode is used as the rear electrode 12, or a structure is further provided for sealing all or part of the light element 10 with a resin or a ceramic. Furthermore, a modification example as shown in FIG. 2 is also possible. A phosphor element 20 shown in FIG. 2 is different as compared with the phosphor element 10 shown in FIG. 1, in that the electrodes are reversed in terms of polarity and arrangement. Light emitted from the phosphor layer 13 is extracted through transparent electrode 16 and a transparent substrate 11 toward the outside of the element. Furthermore, a modification example as shown in FIG. 3 is also possible. A phosphor element 30 shown in FIG. 3 is different as compared with the phosphor element 10 shown in FIG. 1, in that a hole injection layer 31 is further provided between a transparent electrode 16 and a phosphor layer 13. This lowers the driving voltage of the phosphor element 30, and improves the stability in hole injection from the electrode.

The respective components of the phosphor element will be described below in detail with reference to FIGS. 1 to 3.

### <Substrate>

In FIG. 1, for the substrate 11, a substrate is used which is able to support respective layers formed on the substrate. Specifically, silicon, ceramics such as Al₂O₃ and AlN, and the like can be used. Furthermore, plastic substrates such as a polyester and a polyimide may be used. In addition, when light is extracted from the side of the substrate 11, the substrate 11 is required to be a light transmitting material with respect to the wavelength of light emitted from a light emitter. As such a material, for example, glass such as Corning 1737, quartz, and the like can be used. In order to prevent alkali ions and the like contained in normal glass from having an effect on the phosphor element, the material may be non-alkali glass, or soda lime glass with a glass surface coated with alumina or the like as an ion barrier layer. These are examples, and the material of the substrate 11 is not considered limited to these examples.

Alternatively, when no light is extracted from the substrate side, the light transmitting property described above is not required, and materials without any light transmitting property can also be used.

### <Electrode>

The electrodes include the rear electrode 12 and the transparent electrode 16. Of the two electrodes, the electrode on the side from which light is extracted is used as the transparent electrode 16, whereas the other is used as the rear electrode 12.

The material of the transparent electrode 16 on the side from which light is extracted may be any material as long as the material has a light transmitting property so that light generated in the phosphor layer 13 can be extracted, and preferably has a high transmittance, in particular, in a visible light region. Furthermore, the material is preferably a low resistance material, and further, preferably has excellent adhesion with the phosphor layer 13. Furthermore, a material is more preferable which can be deposited on the phosphor layer 13 at a low temperature so as to prevent the phosphor layer 13 from being thermally deteriorated. Materials which are particularly preferred as the material of the transparent electrode 16 include, but are not particularly limited to, metal oxides based on an ITO (In₂O₃ doped with SnO₂, which is also referred to as an indium tin oxide), InZnO, ZnO, SnO₂, or the like; metal thin films such as Pt, Au, Pd, Ag, Ni, Cu, Al, Ru, Rh, and Ir; or conductive polymers such as a polyaniline, a polypyrrole, PEDOT/PSS, and a polythiophene. Furthermore, the transparent electrode 16 desirably has a volume resistivity of 1×10⁻³ Ωcm or less, a transmittance of 75% or more for wavelengths from 380 nm to 780 nm, and a refractive index from 1.85 to 1.95. For example, an ITO can be deposited by a deposition method such as sputtering, electron beam evaporation, or ion plating, for the purpose of improving the transparency or lowering the resistivity. Furthermore, after the deposition, surface treatment such as a plasma treatment may be applied for the purpose of controlling the resistivity. The film thickness of the transparent electrode 16 is determined from the required sheet resistance and visible light transmittance.

An ITO can be deposited by a deposition method such as sputtering, electron beam evaporation, or ion plating, for the purpose of improving the transparency or lowering the resistivity. Furthermore, after the deposition, surface treatment such as a plasma treatment may be applied for the purpose of controlling the resistivity. The film thickness of the transparent electrode is determined from the required sheet resistance and visible light transmittance. While the transparent electrode 16 may be directly formed on the phosphor layer 13, a transparent conductive film may be formed on a glass substrate and attached so that the transparent conductive film comes in contact with the phosphor layer 13.

The rear electrode 12 on the side from which no light is extracted may be any electrode as long as the electrode is electrically conductive and has excellent adhesion with the substrate 11 and the phosphor layer 13. As preferred examples, for example, metal oxides such as ITO, InZnO, ZnO, and SnO₂, metals such as Pt, Au, Pd, Ag, Ni, Cu, Al, Ru, Rh, Ir, Cr, Mo, W, Ta, Nb, and laminated structures thereof, or conductive polymers such as a polyaniline, a polypyrrole, PEDOT [poly(3,4-ethylene dioxythiophene)]/PSS (polyethylene sulfonic acid), or conductive carbon can be used.

The rear electrode 12 may be configured to cover the entire surface of the layer, or may be configured to have a plurality of stripe-shaped electrodes in the layer. Furthermore, the rear electrode 12 and the transparent electrode 16 may be configured to have a plurality of stripe-shaped electrodes, in such a way that each stripe-shaped electrode of the rear electrode 12 and all of the strip-shaped electrodes of the transparent electrode 16 have a skew relationship with each other and that projections of each stripe-shaped electrode of the rear electrode 12 onto the light emitting surface and projections of all of the stripe-shaped electrodes of the rear electrode 16 onto the light emitting surface intersect with each other. In this case, the application of a voltage to the electrodes selected respectively from the respective stripe-shaped electrodes of the rear electrode 12 and the respective striped-shaped electrodes of the transparent electrode 16 allows a display to be configured in such a way that light is emitted in a predetermined position. It is to be noted that the same applies to the structure in FIG. 3.

### <Phosphor Layer>

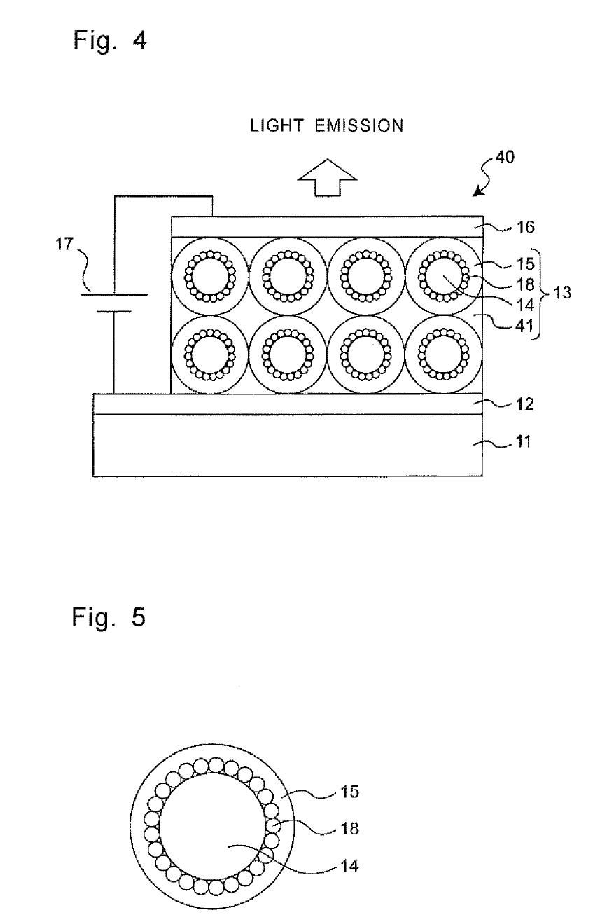

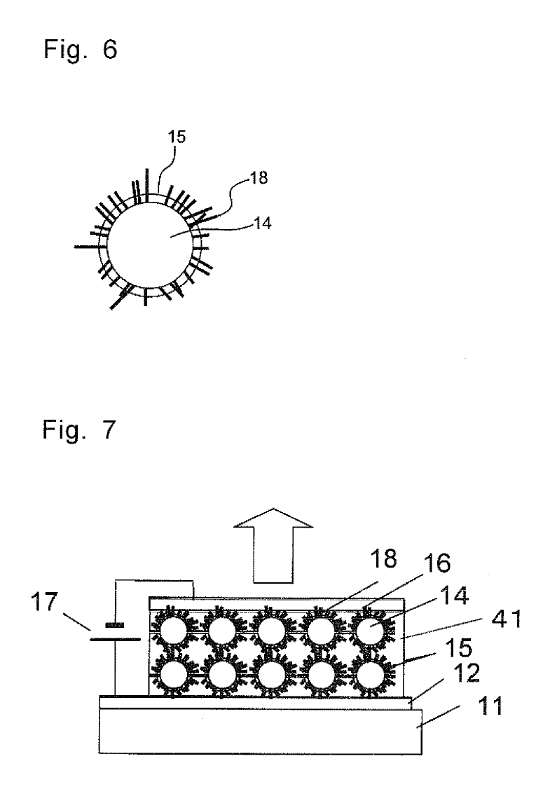

The phosphor layer 13 is configured in such a way that the phosphor particles 14 are dispersed in the hole transport material 15 as a medium. The conductive nano particles 18 are held on the surface of each of the phosphor particles 14 (FIGS. 1, 2, and 3). It is to be noted that the phosphor layer 13 is not limited to this example, and may include phosphor particle powder (FIG. 4) including light emitting composite particles (FIG. 5) with conductive nano particles 18 held on the surface of each of phosphor particles 14 and further covered thereon with a hole transport material 15, as in a phosphor layer in a phosphor element according to second embodiment. Alternatively, as in a phosphor element according to third embodiment, the phosphor layer 13 may include phosphor particle powder (FIG. 6) including light emitting composite particles (FIG. 7) with conductive nano particles 18 held on the surface of each of phosphor particles 14, covered thereon with a hole transport material 15, and some of the conductive nano particles 18 exposed from the hole transport material to the outside.

### <Phosphor Particle>

As the phosphor particles 14, any material can be used as long as the optical bandgap of the material is as wide as visible light. Specifically, AlN, GaN, InN, AlP, GaP, InP, AlAs, GaAs, AlSb, and the like which are Group XIII-Group XV compound semiconductors can be used. In particular, Group XIII nitride semiconductors typified by GaN are preferable. Furthermore, mixed crystals thereof (for example, GaInN, etc.) may be used. Moreover, in order to control the conductivity, the material may contain, as a dopant, one or more elements selected from the group consisting of Si, Ge, Sn, C, Be, Zn, Mg, Ge, and Mn.

Furthermore, with a nitride such as InGaN or AlGaN, ZnSe or ZnS, or further ZnS, ZnSe, GaP, CdSe, CdTe, SrS, CaS, or ZnO as a mother body, the mother body can be used as it is, or phosphor particles with the addition of one or more elements selected from Ag, Al, Ga, Cu, Mn, Cl, Tb, and Li can be used. In addition, multicomponent compounds such as ZnSSe and thiogallate based phosphor can be also used.

Furthermore, the multiple compositions in the phosphor particles 14 may have a laminated structure or a segregated structure. The phosphor particles 14 may have a particle diameter in the range of 0.1 μm to 1000 μm, more preferably, in the range of 0.5 μm to 500 μm.

### <Conductive Nano Particle>

The conductive nano particles 18 used for the phosphor elements according to the present invention can use metal material particles such as Ag, Au, Pt, Ni, and Cu, oxide particles such as an indium tin oxide, ZnO, and InZnO, carbon material particles such as carbon nanotubes. The shapes of the conductive nano particles 18 may be any shape such as granular, circular, columnar, acicular, or amorphous. The average particle diameter or average length of the conductive nano particles 18 preferably falls within the range of 1 nm to 200 nm. The average particle diameter or average length less than 1 nm results in poor conductivity, decreasing the light emission luminance. On the other hand, the average particle diameter or average length greater than 200 nm increases electrical conduction between the electrodes, while the number of the phosphor particles 14 which are not included in the conductive path is increased, decreasing the light emission luminance and efficiency.

The production of carbon nanotubes is carried out by a method such as a vapor phase synthetic method or plasma method, and depending on the manufacturing conditions, the electrical characteristics, diameters, lengths, and the like of the carbon nanotubes can be arbitrarily varied. As the conductive nano particles held on the surface of each of the phosphor particles 14, which are covered with the hole transmit material 15, p-type carbon nanotubes may be used. The p-type carbon nanotubes are obtained by adding an element such as K or Cs as a dopant to carbon nanotubes.

### <Hole Transport Material>

Next, the hole transport material 15 will be described. The hole transport material 15 covers the surface of the conductive nano particles 18 which is held on the surface of each of the phosphor particles 14. Alternatively, the hole transport material 15 serves as a medium material existing among the phosphor particles 14. Any organic material can be used for the hole transport material 15 as long as the organic material has the function of generating and transporting holes. In addition, as the hole transport material 15, organic hole transport materials and inorganic hole transport materials are cited. The hole transport material 15 is preferably a material with a high hole mobility.

### <Organic Hole Transport Material>

This organic hole transport material preferably contains components of the following chemical formula 6 and chemical formula 7.

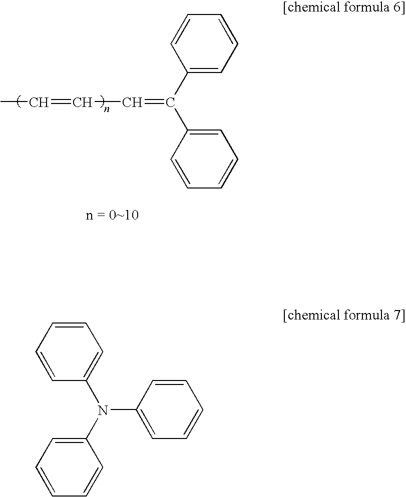

It is believed that the advantageous effect of the organic hole transport material containing the components of the above chemical formula 6 and chemical formula 7 is efficient injection of holes for the phosphor particles 14.

Furthermore, this organic hole transport material may contain any of the following chemical formula 8, chemical formula 9, and chemical formula 10 as a component.

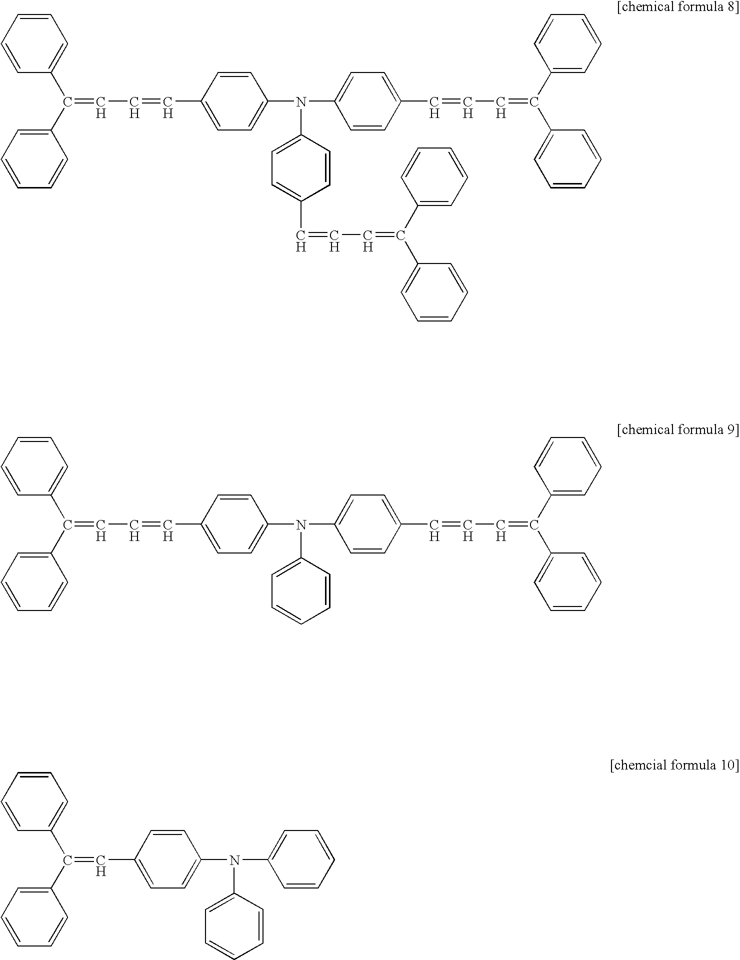

In addition, the main types of organic hole transport materials are low-molecular-weight materials and high-molecular-weight materials. Low-molecular-weight materials which have a hole transport property include diamine derivatives used by Tang et al., such as N,N′-bis(3-methylphenyl)-N,N′-diphenylbenzidine (TPD) and N,N′-bis(α-naphthyl)-N,N′-diphenylbenzidine (NPD), in particular, diamine derivatives which has a Q1-G-Q2 structure, disclosed in Japanese Patent No. 2037475, where Q1 and Q2 are separately a group having a nitrogen atom and at least three carbon chains (at least one of the carbon chains comes from an aromatic group), and G is a linking group including a cycloalkylene group, an arylene group, an alkylene group or a carbon-carbon bond. Alternatively, the organic hole transport material may be polymers (oligomers) including these structural units. These polymers include polymers which have a spiro structure or a dendrimer structure. Furthermore, the form in which molecules of a low-molecular-weight hole transport material are dispersed in a nonconductive polymer is likewise available. Specific examples of the molecular dispersion system include an example in which molecules of TPD are dispersed in high concentration in a polycarbonate, with the hole mobility on the order of 10⁻⁴ to 10⁻⁵ cm²/Vs.

Moreover, other examples of the hole transport material include tetraphenyl butadiene materials, hydrazine materials such as 4-(bis(4-methylphenyl)amino)benzaldehyde diphenylhydrazine, stilbene materials such as 4-methoxy-4′-(2,2′-diphenylvinyl)triphenylamines, PEDOT (poly(2,3-dihydrocyano-1,4dioxin)), α-NPD, DNTPD, and a Cu phthalocyanine.

On the other hand, high-molecular-weight materials which has a hole transport property include π-conjugated polymers and σ-conjugated polymers, and for example, a high-molecular-weight material in which an arylamine compound is incorporated. Specifically, the high-molecular-weight materials include, but are not limited to, poly-para-phenylenevinylene derivatives (PPV derivatives), polythiophenes derivatives (PAT derivatives), polyparaphenylene derivatives (PPP derivatives), polyalkylphenylene (PDAF), polyacetylene derivatives (PA derivatives), and polysilane derivatives (PS derivatives). Furthermore, the high-molecular-weight materials may be polymers with a low-molecular-weight hole-transport molecular structure incorporated into their molecular chains, and specific examples of the polymers include polymethacrylamides with an aromatic amine in their side chains (PTPAMMA, PTPDMA) and polyethers with an aromatic amine in their main chains (TPDPES, TPDPEK). Above all, as a particularly preferred example, above all, poly-N-vinylcarbazole (PVK) exhibits an extremely high hole mobility of 10⁻⁶ cm²/Vs. Other specific examples include PEDOT/PSS and polymethylphenylsilane (PMPS).

Moreover, more than one type of the hole transport materials mentioned above may be mixed and used. Furthermore, the organic hole transport material may contain a crosslinkable or polymerizable material which is cross-linked or polymerized by light or heat.

### <Inorganic Hole Transport Material>

Inorganic hole transport materials will be described. The inorganic hole transport material may be any material as long as the material is transparent or semi-transparent and exhibits p-type conductivity. Preferred inorganic hole transport materials include metalloid semiconductors such as Si, Ge, SiC, Se, SeTe, and As₂Se₃; binary compound semiconductor such as ZnS, ZnSe, CdS, ZnO, and CuI; chalcopyrite semiconductors such as CuGaS₂, CuGaSe₂, and CuInSe₂, and further mixed crystals of these semiconductors; and oxide semiconductors such as CuAlO₂ and CuGaO₂, and further mixed crystals of these semiconductors. Moreover, a dopant may be added to these materials, in order to control the conductivity.

### Example

As an example of the present invention, a method for obtaining the phosphor layer 13 by an application method will be described. As an example, a phosphor element 20 was manufactured as shown in FIG. 2.

(a) As the transparent substrate 11 with the transparent electrode 16 provided, glass was used with an ITO as the transparent electrode 16 deposited thereon by sputtering. The film thickness of the ITO 16 was about 300 nm.

(b) GaN particles with their average particle diameter from 500 nm to 1000 nm were used as the phosphor particles 14.

(c) With the use of ITO nano particles with their average particle diameter from 20 nm to 30 nm as the conductive nano particles 18, the ITO nano particles 18 were fixed on the surface of each of the GaN particles 14.

(d) With the use of tetraphenylbutadiene T770 dissolved in a resin solution as the hole transport material 15, the GaN particles 14 with the conductive nano particles 18 held on the surface of each of the GaN particles 14 were well mixed into a resin paste made of a hole transport material to obtain a light emitting paste.

(e) Next, the light emitting paste was applied on the glass substrate 11 with the ITO film 16 deposited thereon to form an applied film to serve as the phosphor layer 13. The thickness of the applied film was about 30 μm.

(f) Next, a rear electrode 12 including a silicon substrate with a Pt electrode formed thereon was attached so that the Pt electrode surface of the silicon substrate comes in contact with the applied film. After that, the applied film was dried to obtain the dried film as the phosphor layer 13.

In accordance with the steps described above, the phosphor element was prepared.

The evaluation of the prepared phosphor element was carried out by applying a direct-current voltage from the power supply 17 between the rear electrode 12 and the transparent electrode 16 to confirm whether or not light was emitted. Furthermore, the luminance measurement was carried out with the use of a portable luminance meter. The results show that the phosphor element started to emit orange light at a direct-current voltage of 5V and produced a light emission luminance of about 3500 cd/m² at 15V.

It is to be noted that while the positive voltage and the negative voltage were applied respectively to the rear electrode 12 and the transparent electrode 16 in the present example, the phosphor element was allowed to emit light likewise even when the polarity was changed.

### Advantageous Effects

The phosphor element according to the present embodiment is excellent in corrosion resistance and oxidation resistance and has a higher luminance and a longer lifetime than conventional phosphor elements.

### Second Embodiment

### <Schematic Structure of Phosphor Element>

A phosphor element according to second embodiment of the present invention will be described with reference to FIGS. 4 and 5. FIG. 4 is a cross-sectional view perpendicular to a light emitting surface, illustrating the schematic structure of a phosphor element 40 according to second embodiment. This phosphor element 40 is different as compared with the phosphor element 10 shown in FIG. 1, in that the phosphor layer 13 includes phosphor particle powder including light emitting composite particles shown in FIG. 5. FIG. 5 is a cross sectional view illustrating the cross section structure of a light emitting composite particle with conductive nano particles 18 held on the surface of each of phosphor particles 14 and further coated thereon with a hole transport material 15. The coated layer of the hole transport material has a thickness in the range 1 μm to 10 μm, preferably in the range of 2 μm to 3 μm. Furthermore, this phosphor element 40 is different as compared with the phosphor element according to the first embodiment, in that the light emitting composite particles described above are arranged between the rear electrode 12 and the transparent electrode 16 with an organic binder 41 as a binding agent. The phosphor element 40 according to the second embodiment is characterized in that the conductive nano particles held on the surface of each of the phosphor particles 14 and coated thereon with the organic hole transport material 15 improve the hole injection property, and also improve the electron injection property.

As the binder 41, any insulating resin past can be used. It is to be noted that the embodiment is not limited to the structure described above, changes can be appropriately made, in such a way that a black electrode is used as the rear electrode 12, or a structure is further provided for sealing all or part of the light element 40 with a resin or a ceramic.

### Advantageous Effects

The phosphor element according to the present embodiment is able to form a planar shape with relative ease, and can achieve a phosphor element with a high luminance, a high efficiency, and high reliability.

### Third Embodiment

### <Schematic Structure of Phosphor Element>

A phosphor element 50 according to third embodiment of the present invention will be described with reference to FIGS. 6 and 7. FIG. 7 is a cross-sectional view perpendicular to a light emitting surface, illustrating the schematic structure of a phosphor element 50 according to third embodiment. This phosphor element 50 is different as compared with the phosphor element 10 shown in FIG. 1, in that the phosphor layer 13 includes phosphor particle powder including light emitting composite particles shown in FIG. 6. FIG. 6 is a cross sectional view illustrating the cross section structure of a light emitting composite particle with conductive nano particles 18 held on the surface of each of phosphor particles 14, coated thereon with a hole transport material 15, and some of the conductive nano particles 18 exposed from the hole transport material to the outside. The coated layer of the hole transport material has a thickness in the range of 1 μm to 10 μm, preferably in the range of 2 μm to 3 μm. Furthermore, this phosphor element 50 is different as compared with the phosphor element according to the first embodiment, in that the light emitting composite particles described above are arranged between the rear electrode 12 and the transparent electrode 16 with an organic binder 41 as a binding agent. The phosphor element 50 according to the third embodiment is characterized in that the conductive nano particles held on the surface of each of the phosphor particles 14 and coated thereon with the organic hole transport material 15, as well as some of the conductive nano particles 18 are exposed to improve the hole injection property, and also to improve the electron injection property.

### Fourth Embodiment

### <Schematic Structure of Phosphor Element>

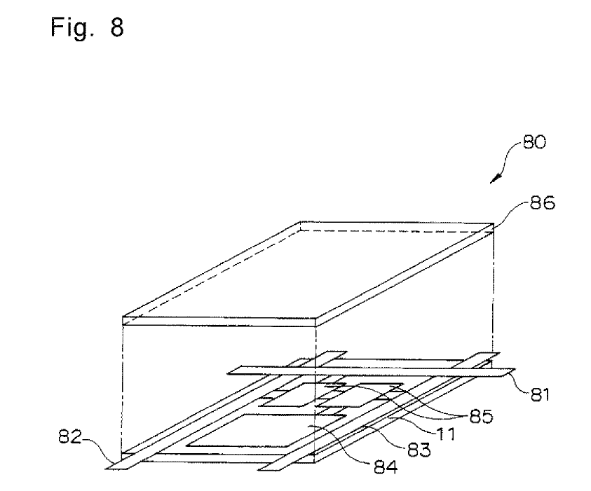

A phosphor element according to fourth embodiment of the present invention will be described with reference to FIG. 8. FIG. 8 is a perspective view illustrating the electrode composition of the phosphor element 80. This phosphor element 80 further includes thin film transistors (hereinafter, abbreviated as TFTs, and including two TFTs of a switching TFT and a driving TFT in FIG. 8) 85 connected to the pixel electrodes 84. The TFTs 85 are connected to a scan line 81, a data line 82, and a current supply line 83. In this phosphor element 80, since light emission is extracted from the side of a transparent common electrode 86, the aperture ratio can be adjusted higher regardless of the arrangement of the TFTs 85 on a substrate 11. Furthermore, the use of the TFTs 85 allows the phosphor element 80 to have a memory function. As the TFTs 85, low temperature polysilicon TFTs, amorphous silicon TFTs, organic TFTs including organic materials such as pentacene can be used. Moreover, the TFTs 85 may be inorganic TFTs composed of ZnO, InGaZnO₄, etc.

### Fifth Embodiment

<Schematic Structure of Display Device>

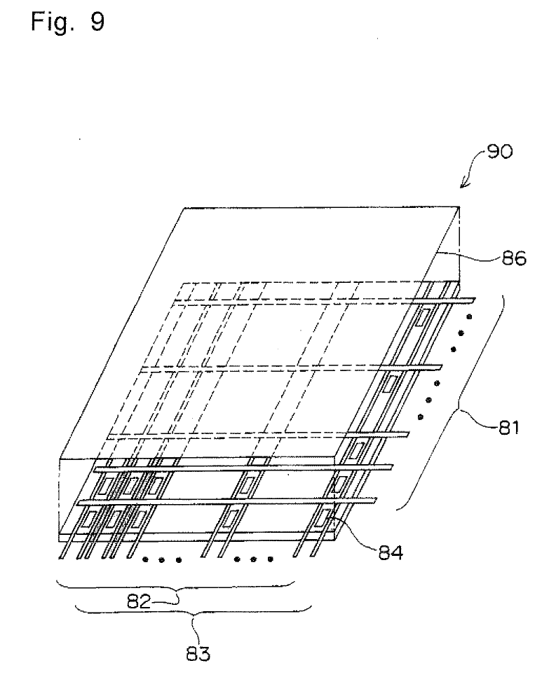

FIG. 9 is a schematic plan view illustrating the configuration of an active matrix display device 90 according to fifth embodiment of the present invention. This display device 90 includes pixel electrodes 84, a common electrode 86, scan limes 81, data lines 82, current supply lines 83, and TFTs (omitted in the figure). This display device 90 further includes a phosphor element array in which the phosphor element shown in FIG. 8 is two-dimensionally arranged in plural, a plurality of scan lines 81 extending parallel to each other in a first direction parallel to the surface of the phosphor element array, a plurality of data lines 82 extending parallel to a second direction parallel to the surface of the phosphor element array and orthogonal to the first direction, and a plurality current supply lines 83 extending parallel to the second direction. The TFTs on this phosphor element array are electrically connected to the scan lines 81, the data lines 82, and the current supply lines 83. The phosphor element specified by a pair of scan line 81 and data line 82 serves as one pixel. Furthermore, in this active matrix display device 90, a current is supplied from the current supply line 83 through the TFT to one pixel selected by the scan line and the data line to drive the selected phosphor element, and the obtained light emission is extracted from the side of the transparent common electrode 86.

Furthermore, in the case of a color display device, the phosphor layers may be deposited separately with the use of phosphor particles for each color of RGB. Alternatively, light emitting units such as electrode/phosphor layer/electrode may be laminated for each of RGB. Moreover, in the case of another color display device, after preparing a display device with phosphor layers for a single color or two colors, color filters and/or color conversion filters can be used to display each color of RGB. For example, RGB display is made possible by providing blue phosphor layers further with filters each for color conversion from a blue color to a green color or from a blue color or a green color to a red color.

### Advantageous Effects

In this active matrix display device 90, the phosphor layer 13 constituting the phosphor element of each pixel is, as described above, configured in such a way that the phosphor particles 14 are dispersed in the hole transport material 15 as a medium and the conductive nano particles 18 are held on the surface of each of the phosphor particles 14, or includes phosphor particle powder including the phosphor particles 14 with conductive nano particles 18 held on the surface of each of the phosphor particles 14 and further coated thereon with the hole transport material 15. This allows a display device with a high light emission luminance, a high luminous efficiency, and high reliability to be achieved.

### Sixth Embodiment

### <Schematic Structure of Display Device>

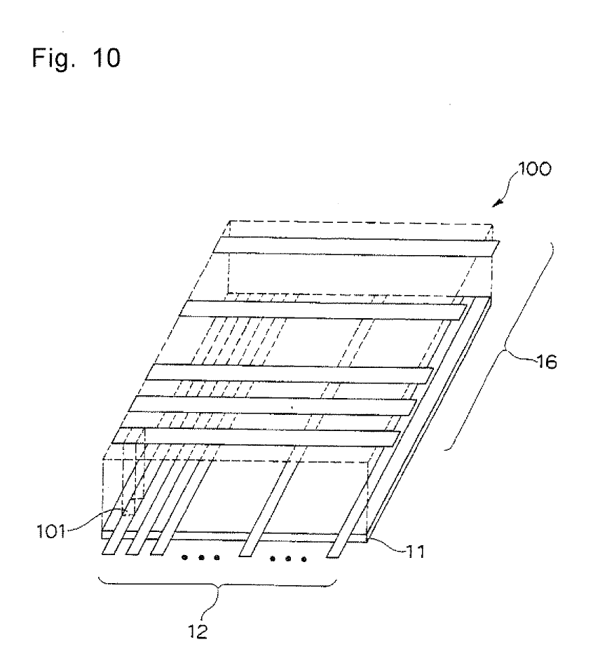

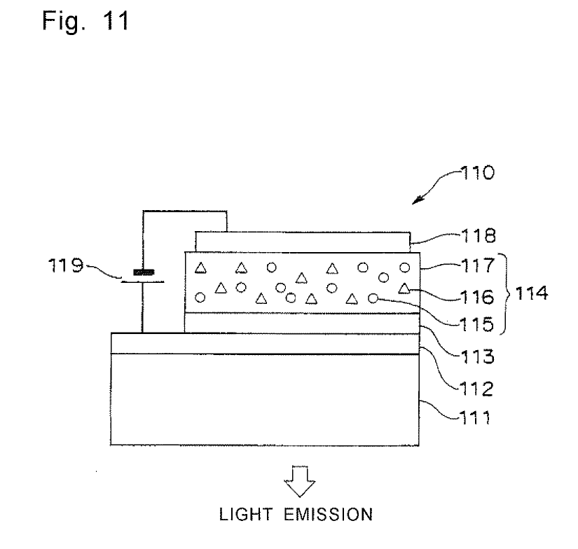

A display device according to sixth embodiment of the present invention will be described with reference to FIG. 10. FIG. 10 is a schematic plan view illustrating a passive matrix display device 100 including rear electrodes 12 and transparent electrodes 16 orthogonal to each other. The passive matrix display device 100 includes a phosphor element array in which a plurality of phosphor elements are two-dimensionally arranged. In addition, the passive matrix display device 100 includes a plurality of rear electrodes 12 extending parallel a first direction parallel to the surface of the phosphor element array, and a plurality of transparent electrodes 16 extending parallel to a second direction parallel to the surface of the phosphor element array and orthogonal to the first direction. Furthermore, in the passive matrix display device 100, an external voltage is applied between a pair of rear electrode 12 and transparent electrode 16 to drive one phosphor element, and the obtained light emission is extracted from the side of the transparent electrode 16. Moreover, it is possible to implement the display device as a color display device in the same way as in fourth embodiment describe above.

### Advantageous Effects

According to this passive matrix display device 100, a display device can be achieved which provides a high light emission luminance, a high luminance efficiency, and high reliability, as in the case of the display device according to fourth embodiment.

The phosphor elements and display devices according to the present invention provide light emissions with a high light emission luminance and with a high luminous efficiency and provide reliability for long periods of time. In particular, the phosphor elements and display devices are useful as display devices such as televisions and a variety of light sources for use in communication, illumination, etc.

The phosphor elements according to the present invention have a high light emission luminance, and thus are available for backlights for LCDs illumination, displays, etc.

1. A phosphor element comprising:
a first electrode and a second electrode arranged to face each other, at least one of the electrodes being transparent or semi-transparent; and
a phosphor layer provided as being sandwiched between the first electrode and the second electrode, the phosphor layer having phosphor particles dispersed in a medium made of a hole transport material, wherein conductive nano particles are held on a surface of each of the phosphor particles.

2. A phosphor element comprising:
a first electrode and a second electrode arranged to face each other, at least one of the electrodes being transparent or semi-transparent; and
a phosphor layer provided as being sandwiched between the first electrode and second electrode, the phosphor layer having phosphor particle powder including phosphor particles, conductive nano particles being held on a surface of each of the phosphor particles, hole transport material being held on at least a portion of the surface of the conductive nano particles.

3. The phosphor element according to claim 2, wherein the conductive nano particles held on the surface of each of the phosphor particles are exposed from the hole transport material to the outside.

4. The phosphor element according to claim 2, wherein the phosphor layer comprises a binder among the phosphor particles.

5. The phosphor element according to claim 1, wherein the hole transport material comprises an organic hole transport material.

6. The phosphor element according to claim 5, wherein the organic hole transport material contains components of the following chemical formula 1 and chemical formula 2.

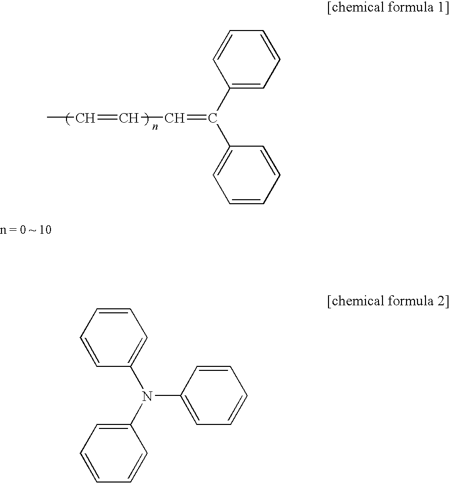

7. The phosphor element according to claim 6, wherein the organic hole transport material further comprises at least one component of the group constituting of the following chemical formula 3, chemical formula 4, and chemical formula 5.

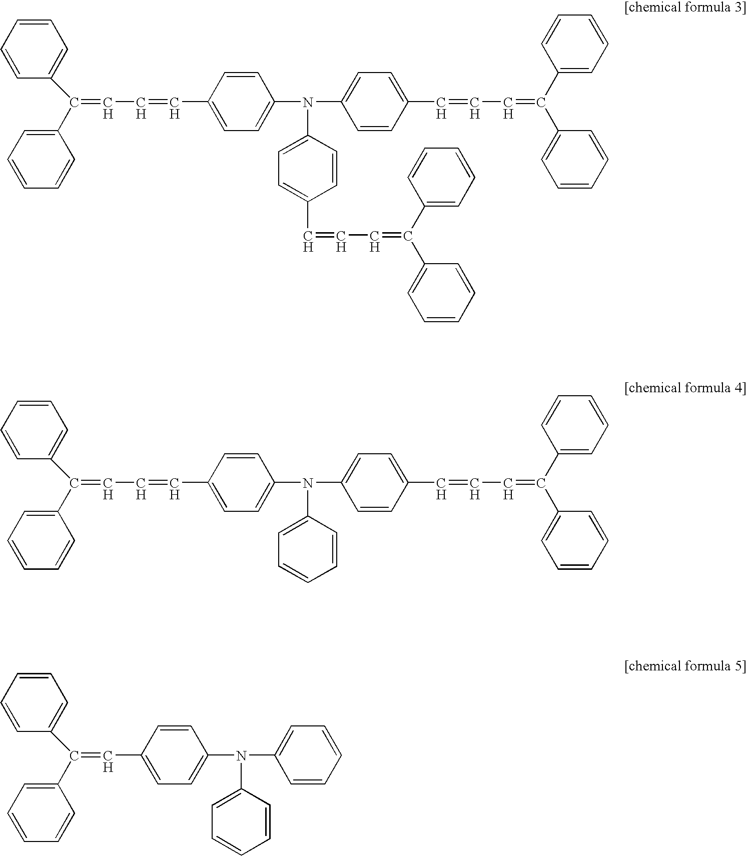

8. The phosphor element according to claim 1, wherein the hole transport material comprises an inorganic hole transport material.

9. The phosphor element according to claim 1, wherein the conductive nano particles comprises at least one metal fine particle selected from the group constituting of Ag, Au, Pt, Ni, and Cu.

10. The phosphor element according to claim 1, wherein the conductive nano particles comprises at least one oxide fine particle selected from the group constituting of an indium tin oxide, ZnO, and InZnO.

11. The phosphor element according to claim 1, wherein the conductive nano particles comprises at least one carbon fine particle selected from the group of fullerene and a carbon nanotube.

12. The phosphor element according to claim 1, wherein the conductive nano particles have an average particle diameter within the range of 1 to 200 nm.

13. The phosphor element according to claim 1, wherein the phosphor particles comprise a particle containing a Group XIII-Group XV compound semiconductor.

14. The phosphor element according to claim 1, wherein the phosphor particles comprise at least one phosphor material selected from the group of a nitride, a sulfide, a selenide, and an oxide.

15. The phosphor element according to claim 13, wherein the phosphor particles are nitride semiconductor particles comprising at least one element of Ga, Al, and In.

16. The phosphor element according to claim 15, wherein the phosphor particles are phosphor particles containing GaN.

17. The phosphor element according to claim 1, wherein the phosphor particles have an average particle diameter within the range of 0.1 μm to 1000 μm.

18. The phosphor element according to claim 1, further comprising a hole injection layer sandwiched between the first electrode and the phosphor layer.

19. The phosphor element according to claim 1, further comprising a support substrate facing the first electrode or the second electrode for support.

20. The phosphor element according to claim 19, wherein the support substrate is a glass substrate or a resin substrate.

21. The phosphor element according to claim 20, further comprising one or more thin film transistors connected to the first electrode or the second electrode.

22. A display device comprising:
a phosphor element array in which the phosphor element according to claim 1 is two-dimensionally arranged in plural;
a plurality of x electrodes extending parallel to each other in a first direction parallel to a light emitting surface of the phosphor element array; and
a plurality of y electrodes extending parallel to a second direction parallel to the light emitting surface of the phosphor element array and orthogonal to the first direction.

23. A display device comprising:
a phosphor element array in which the phosphor element according to claim 21 is two-dimensionally arranged in plural;
a plurality of signal wirings extending parallel to each other in a first direction parallel to a light emitting surface of the phosphor element array; and
a plurality of scan wirings extending parallel to second direction parallel to the light emitting surface of the phosphor element array and orthogonal to the first direction,
wherein one electrode connected to the thin film transistor of the phosphor element array is a pixel electrode corresponding to respective intersection of the signal wiring and the scan wiring, whereas the other electrode is provided which is common to the plurality of phosphor elements.

24. The display device according to claim 22, further comprising a color conversion layer anteriorly in a direction of light emission extraction.
